(19) United States
(12) Patent Application Publication
(10) Pub. No.: US 2009/0066260 A1
(43) Pub. Date: Mar. 12, 2009

(54) Driving circuit for a display panel and a display having same

(75) Inventor: Terukazu Sugimoto, Chiba-ken (JP)

Correspondence Address: BACON & THOMAS, PLLC, 625 SLATERS LANE, FOURTH FLOOR, ALEXANDRIA, VA, 22314-1176, US

(73) Assignee: Futaba Corporation, Chiba (JP)

(21) Appl. No.: 12/232,110

(22) Filed: Sep. 11, 2008

(30) Foreign Application Priority Data
Sep. 12, 2007 (JP) 2007-236450

(51) Int. Cl. G09G 3/32; H01L 27/32

(52) U.S. Cl. 315/169.3; 345/212

(57) ABSTRACT

There is provided a driving circuit capable of driving current flowing in cathode electrodes with high accuracy and displaying without brightness variation. For driving a cathode electrode in a display panel, a first current mirror circuit is fabricated by connecting a gate of first FET and a gate of second FET and a second current mirror circuit is fabricated by connecting a gate of a third FET connected in series to the second FET and a gate of a fourth FET. A brightness signal controls the magnitude of current flowing in the first FET, so that the current flowing to the cathode electrode via the fourth FET can be controlled with high accuracy.

### FIELD OF THE INVENTION

The present invention relates to a driving circuit for a display panel and a display having same.

### BACKGROUND OF THE INVENTION

With a recent trend toward a thin display, a display using a field emission device (hereinafter, referred to as “FED”) and a display using an organic electroluminescent (hereinafter, referred to as “EL”) device are expected to be widely applied as displays for household and industrial use. In these displays, display devices are arranged in a two-dimensional space to form a display panel, and the display panel thus formed is driven by a driving circuit. Although a driving circuit for the FED is different in circuit parameters from a driving circuit for the EL device, both have a common driving principle. In the following description, a driving circuit for the FED will be mainly explained. However, this description can also be applied to the EL device.

In the FED, electrons are emitted through a tunnel effect from a metal surface or a semiconductor surface of which electric field strength is about 10⁹ V/m. FIG. 10 is a cross sectional view of a spindt type FED. This FED is fabricated by forming on an insulating substrate 100 a cathode electrode 101, a gate electrode 102 and a molybdenum cone-shaped emitter 103 electrically connected to the cathode electrode 101, each of which is formed of a conductive material. Further, an SiO₂ film is formed between the cathode electrode 101 and the gate electrode 102 to insulate them from each other and maintain a predetermined distance therebetween.

Moreover, in order to capture electrons emitted from the FED, an anode electrode 104 coated with phosphor is disposed in a position separated with a gap from the gate electrode. When a gate-cathode voltage V_{GC} is applied between the cathode electrode 101 and the gate electrode 102, electrons are emitted. Further, an anode voltage V_{A} is applied between the cathode electrode 101 and the anode electrode 104, so that the electrons emitted from the emitter 103 collide with the phosphor of the anode electrode 104 to thereby emit light. At this time, a cathode current Ic flows between the anode electrode 104 and the cathode electrode 101.

FIG. 11 illustrates a cathode current Ic as a function of (a gate-cathode voltage V_{GC} of a spindt type FED. When the gate-cathode voltage V_{GC} is greater than a threshold value V_{TH}, the cathode current Ic starts to flow. As the gate-cathode voltage V_{GC} increases, the cathode current Ic increases. The increase in the cathode current Ic leads to the increase in the amount of light emitted from the phosphor. Therefore, the amount of light emitted from the phosphor can be controlled by controlling the gate-cathode voltage V_{GC}. V_{OP} and I_{OP} in the figure represent operation V_{GC} and Ic.

FIG. 12 depicts an equivalent circuit of the spindt type FED shown in FIG. 10. A resistance Rc indicates a resistance between the cathode electrode 101 and the emitter 103. As shown in FIG. 12, a pulse voltage V_{C} is applied to the cathode electrode 101 (not shown in FIG. 12) connected to the resistance Rc, and a pulse voltage V_{G} is applied to the gate electrode 102. Depending on the combination of the pulse voltage V_{C} and the pulse voltage V_{G} applied, the gate-cathode voltage V_{GC} is controlled, so that the electric field emission can be controlled.

FIG. 13 schematically shows a part of a display panel forming a display by using FEDs as display devices arranged in a two-dimensional space. In the display panel, a plurality of cathode electrodes and a plurality of gate electrodes are arranged in a matrix shape to intersect with each other. The SiO₂ layer shown in FIG. 10 is omitted in FIG. 13 for the sake of simplicity. Although only cathode electrodes 101₁ to 101₃ and gate electrodes 102₁ to 102₃ are illustrated in FIG. 13, the numbers of cathode electrodes and gate electrodes are properly determined depending on the use. An FED having, e.g., nine emitters, is formed at each intersection point of the cathode electrodes with the gate electrodes.

FIG. 14 provides a conceptual diagram for explaining how to drive the display panel by a driving circuit 120. Here, high levels of the pulse voltage V_{G} and the pulse voltage V_{C} generated by the driving circuit 120 are respectively set to about 50 V and 30 V, and low levels thereof are set to 0 V. Since a voltage difference between the pulse voltage V_{G} and the pulse voltage V_{C} is applied as a gate-cathode voltage V_{GC} to each FED, four gate-cathode voltages V_{GC} of 50 V, 20 V, 0 V and −30 V can be applied to each FED corresponding to a single dot (hereinafter, one or more emitters disposed at each intersection point are referred to as a “dot”).

When a threshold value is set to be greater than 20 V, e.g., 30 V, electrons are emitted only from dots to which a gate-cathode voltage V_{GC} of 50 V is applied. For instance, in the example of FIG. 14, electrons are emitted only from dots positioned at the intersection point of the gate electrode 102₃ and the cathode electrode 101₁ and that of the gate electrode 102₃ and the cathode electrode 101₃. Accordingly, light is emitted only from the phosphors corresponding to the dots. The hatched dots in FIG. 14 correspond to those from which electrons are emitted. Further, in order to adjust emission brightness, the pulse voltage, e.g., V_{C} or V_{G} is adjusted such that the gate-cathode voltage V_{GC} is set to be greater than or equal to the threshold voltage (e.g., 30 V) and correspond to the desired emission brightness. Moreover, a voltage of about 3 KV with respect to the cathode electrode is applied to the anode electrode (not shown in FIGS. 13 and 14) coated with phosphor.

The above description on the FED can also be applied to an EL, even though the EL does not include gate electrodes, by forming a panel structure in which cathode electrodes and anode electrodes corresponding to gate electrodes of the FED are made to intersect with each other and distributing potentials between the anode electrodes and cathode electrodes of the EL in a similar way as in V_{GC} of the FED.

In accordance with the above method, it is possible to control electron emission from dots by controlling voltages of the gate electrodes and the cathode electrodes arranged in a matrix shape. However, the above method has following drawbacks. FIG. 15 shows a comparison between characteristics obtained when accumulated operation time is short (initial characteristics) and those obtained when accumulated operation time is long (after-use characteristics). The current emission performance of the emitter deteriorates due to use for a long period of time. Thus, even if the gate-cathode voltage V_{GC} is set to be the same, lower cathode current Ic flows when the accumulated operation time is long compared to the case when the accumulated operation time is short. Further, since almost no current flows from the cathode electrode to the gate electrode, a magnitude of cathode current of an FED corresponding to a current contribution from a single dot is substantially the same as that of anode current.

FIG. 16 compares current emission performances from different dots in the display panel of the display. In FIG. 16, curved lines indicated as dots A to C represent cathode current Ic flowing at the corresponding dots formed at different intersection portions between the cathode electrode and the anode electrode.

The relationship between the gate-cathode V_{GC} and the cathode current Ic may be varied in time depending on an accumulated operation time of a display (hereinafter, referred to as “temporal variation in characteristics) and may also be varied depending on dot position (hereinafter, referred to as “spatial variation in characteristics”), so that the emission brightness may vary in time and space (hereinafter, referred to as “brightness variation”).

The temporal variation in characteristics due to accumulated operation time is believed to occur when contaminants are adhered or when the gate electrode or the emitter deteriorates due to use for a long period of time. Further, the temporal variation in characteristics varies depending on dots. The spatial variation in characteristics of dots is considered due to the variation in a dimension of a gate hole formed in the gate electrode or a cone shape of the emitter produced during the manufacturing process.

In order to solve the problem of brightness variation, there are employed a voltage control type that controls emission brightness by adjusting a voltage between a cathode electrode or an anode electrode or a current control type that controls emission brightness by adjusting a magnitude of a cathode current flowing in a dot directly related to the emission brightness to be controlled. Further, as a driving method suitable for the current control type, an active matrix type is employed. In the active matrix type, a circuit is added to each dot positioned at an intersection portion of a cathode electrode and a gate electrode and to thereby adjust a magnitude of a cathode current flowing in a dot.

### [Patent Document 1]

Japanese Patent Laid-open Publication No. H9-305139

### [Patent Document 2]

Japanese Patent Laid-open Publication No. 2000-173445

However, the active matrix type can be realized by adding circuits to respective dots of the display panel in a same semiconductor fabrication process during which the display panel is fabricated. Therefore, the active matrix type requires a high-level technique and a high manufacturing cost. Further, the display panel and the driving circuit are fabricated as a unit, so that the combination of the display and the driving circuit is restricted. Accordingly, a product cannot be made by adding a new driving circuit to a conventional display panel or by adding a new display panel to a conventional driving circuit and, also, a long period of time is required from designing to shipping of the product. Moreover, although a current needs to be controlled with high accuracy, it is difficult to secure sufficient current accuracy in a conventional circuit.

### SUMMARY OF THE INVENTION

In view of the above, the present invention provides a driving circuit capable of driving a display panel without employing an active matrix type and a display having same.

In accordance with an aspect of the present invention, there is provided a driving circuit of a display panel for driving a first electrode of the display panel in which the first electrode and a second electrode arranged to cross each other.

The driving circuit includes a first current mirror circuit formed by connecting a gate of a first FET and a gate of a second FET; a current detecting resistor connected to a drain of the first FET, for detecting a magnitude of the current flowing in the first FET; and a differential amplifier having an output end connected to a gate of the first FET, a positive input end connected to a connection node between the first FET and the current detecting resistor, and a negative input end to which a current control signal for controlling a magnitude of the current flowing in the first FET is inputted.

The driving circuit further includes a second current mirror circuit formed by connecting a gate of a third FET connected in series to the second FET to a gate of a fourth FET; an analog switch device connected in series to the fourth FET and the first electrode; and a cathode address control unit for controlling the analog switch device to be a conductive state or a non-conductive state.

In the driving circuit of the display panel in accordance with the aspect of the present invention, there are provided the first and the second current mirror circuit and, also, the second FET of the first current mirror circuit is connected in series with the third FET of the second current mirror circuit. Accordingly, a current having a magnitude in accordance with the current flowing in the first FET can be made to flow into the fourth FET. Further, the magnitude of the current flowing in the first FET can be controlled in accordance with the magnitude of the current control signal. Moreover, the fourth FET and the analog switch device are connected in series to the first electrode, so that the analog switch device can be controlled to be in a conductive state or a non-conductive state by the cathode address control unit. As a consequence, it is possible to control a magnitude of a current flowing in the first electrode with high accuracy in accordance with a current control signal, and also possible to control a conductive state and a non-conductive state of the current by the cathode address control unit.

In accordance with another aspect of the present invention, there is provided a display including a display panel in which a plurality of first electrodes and a plurality of second electrodes are arranged to cross each other; a first driving circuit for driving the first electrodes of the display panel; and a second driving circuit for driving the second electrodes of the display panel.

The first driving circuit includes a first current mirror circuit formed by connecting a gate of a first FET to a gate of a second FET; a current detecting resistor connected to a drain of the first FET, for detecting a magnitude of a current flowing in the first FET; and a differential amplifier having an output end connected to a gate of the first FET, a positive input end connected to a connection node between the first FET and the current detecting resistor, and a negative input end to which a current control signal for controlling a magnitude of the current flowing in the first FET is inputted.

The first driving circuit further includes a second current mirror circuit formed by connecting a gate of a third FET connected to the second FET in series and gates of a plurality of fourth FETs; a plurality of analog switch devices connected in series with the first electrodes and the fourth FETs; and a cathode address control unit for controlling each of the analog switch devices to be a conductive state or a non-conductive state.

In the display in accordance with the aspect of the present invention, there are provided a plurality of first and second electrodes intersecting with each other. Therefore, the current at intersection portions can be controlled by the first and the second driving circuit. The first driving circuit has the first current mirror circuit and the second current mirror circuit. Further, the second FET of the first current mirror circuit is connected in series with the third FET of the second current mirror circuit. Accordingly, a current of a magnitude in accordance with the current flowing in the first FET can flow into each of a plurality of fourth FETs. Moreover, the magnitude of the current flowing in the first FET can be controlled in accordance with the current control signal. Furthermore, the fourth FETs and the analog switch devices are connected in series to the first electrode, so that the analog switch device can be controlled between a conductive state and a non-conductive state by the cathode address control unit. As a consequence, it is possible to control a magnitude of a current flowing in the first electrode with high accuracy in accordance with a current control signal, and also possible to control a conductive state and a non-conductive state of the current by the cathode address control unit.

In accordance with the driving circuit of the display panel of the present invention, the current flowing in the first electrode can be driven with high accuracy and, also, a display having no brightness variation can be performed in spite of the variation in characteristics of accumulated driving time and the variation in characteristics at dots. Further, in accordance with the display of the present invention, the current flowing in the first electrode can be driven with high accuracy; an image having no brightness variation can be obtained in spite of the variation in characteristics of accumulated driving time and the variation in characteristics of dots; and the current flowing in the intersection portions between the first electrode and the second electrode can be independently controlled in accordance with the brightness signal.

### BRIEF DESCRIPTION OF THE DRAWINGS

The objects and features of the present invention will become apparent from the following description of embodiments, given in conjunction with the accompanying drawings, in which:

FIG. 1 shows a display in accordance with an embodiment of the present invention;

FIG. 2 describes a part of a principal portion of a driving circuit;

FIG. 3 illustrates another part of the principal portion of the driving circuit;

FIG. 4 provides a graph showing characteristics of an N channel MOSFET;

FIG. 5 depicts still another part of the principal portion of the driving circuit;

FIG. 6 presents a diagram explaining an operation of the display;

FIG. 7 provides another diagram explaining the operation of the display;

FIG. 8 shows a modification of the driving circuit;

FIG. 9 illustrates another modification of the driving circuit;

FIG. 10 offers a cross sectional view of a spindt type FED;

FIG. 11 depicts a cathode current with respect to a gate-cathode voltage of the spindt type FED;

FIG. 12 describes the spindt type FED as an equivalent circuit;

FIG. 13 schematically shows a part of a display panel;

FIG. 14 provides a conceptual diagram for explaining a method for driving the display panel;

FIG. 15 is a diagram for comparing initial characteristics and after-use characteristics of the display; and

FIG. 16 offers a diagram for comparing current emission performances at different dots of the display panel.

### DETAILED DESCRIPTION OF THE EMBODIMENTS

The embodiments of the present invention will be described with reference to the accompanying drawings which form a part hereof.

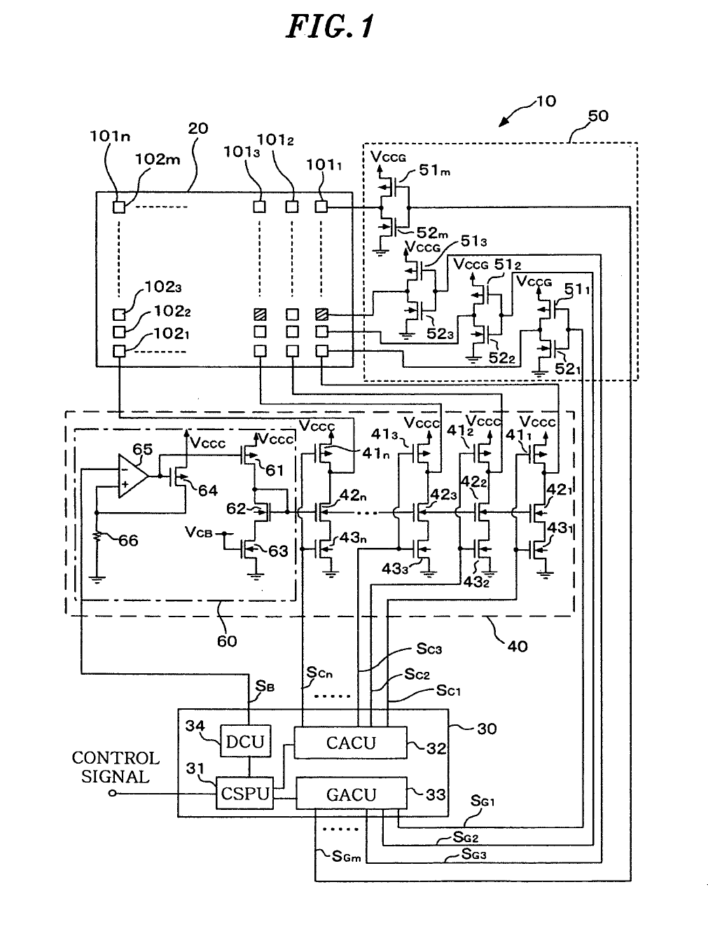

FIG. 1 shows a display 10 in accordance with an embodiment of the present invention. The display 10 includes a display panel 20, a driving unit controller 30, a cathode electrode driving unit 40 and a gate electrode driving unit 50. The driving unit controller 30, the cathode electrode driving unit 40 and the gate electrode driving unit 50 form a driving circuit. In the following, the display panel 20, the driving unit controller 30, the gate electrode driving unit 50 and the cathode electrode driving unit 40 will be described in that order. Thereafter, the operation of the display 10 will be explained.

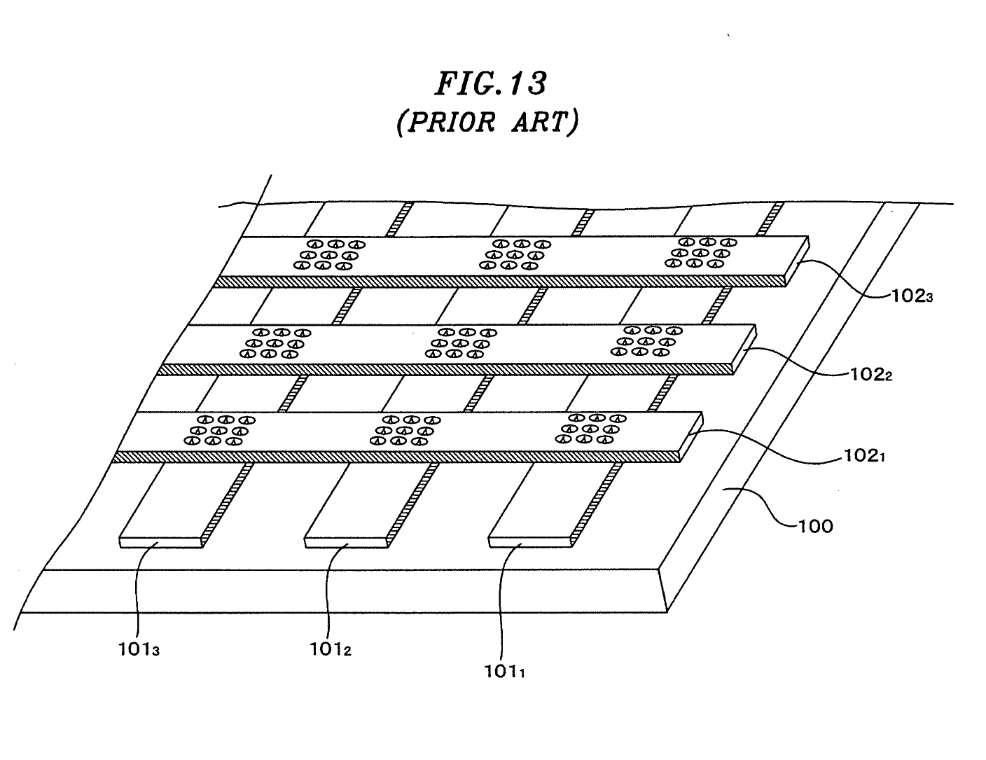

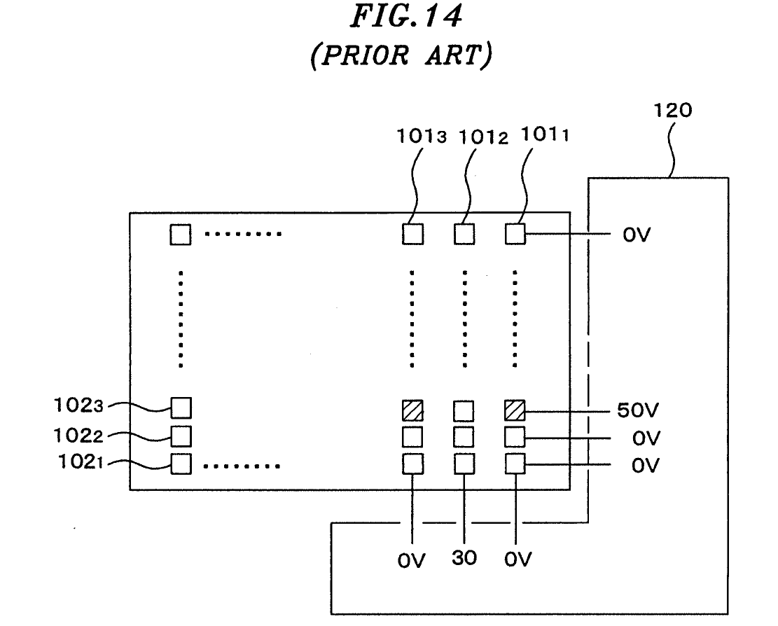

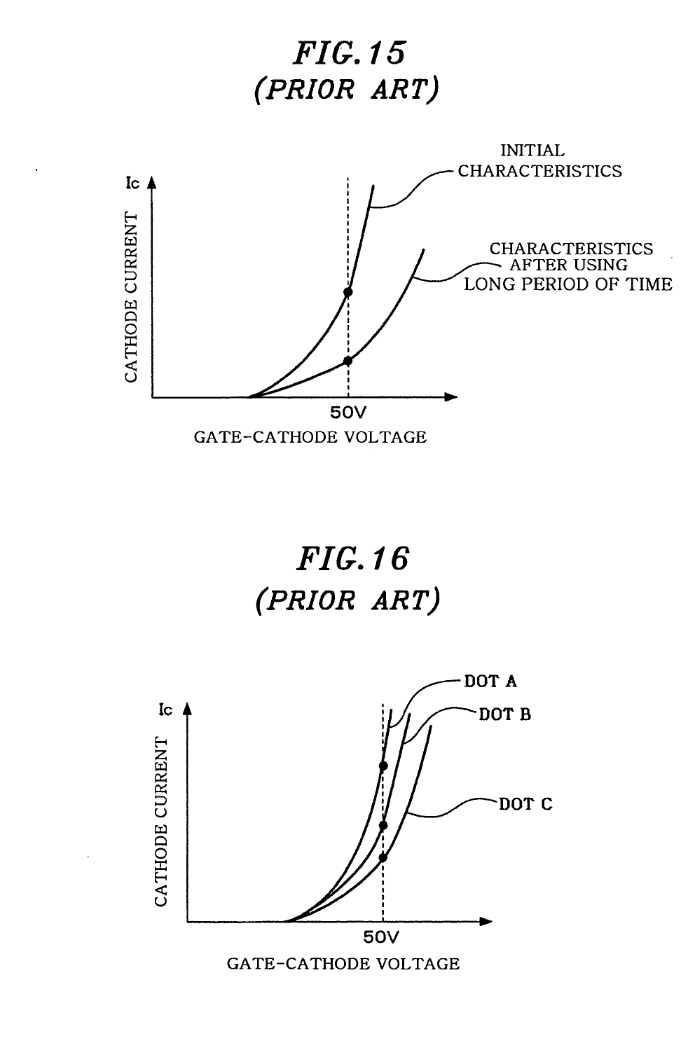

The display panel 20 has the same structure as that of the display panel shown in FIG. 13, so that parts of the common description thereof will be omitted. An n-number of cathode electrodes 101₁ to 101n are arranged in substantially parallel columns, and an m-number of gate electrodes 102₁ to 102ₘ are arranged in substantially parallel rows. Here, n and m are integers that may be same or different. Further, the cathode electrodes and the gate electrodes are disposed to intersect with each other, and each intersection is provided with a dot that includes one or more emitters to form an FED. Although anode electrodes are not illustrated in FIG. 1, the display panel is provided with anode electrodes. Meanwhile, a display panel of an EL display is different from that of an FED in that the anode electrodes for collecting electrons are not provided. Apart from this, a display panel using an EL can also be configured as shown in FIG. 1. Moreover, terms used for the EL are different from those used for the FED. Specifically, a gate electrode of the FED is referred to as an anode electrode in the EL.

Hereinafter, the driving unit controller 30, the gate electrode driving unit 50 and the cathode electrode driving unit 40 forming the driving circuit will be described in that order.

The driving unit controller 30 of the driving circuit receives a control signal from an external device (not shown). The control signal may be either an analog signal or a digital signal, and is divided into a display address signal and a display signal by a control signal processing unit (CSPU) 31. The display signal contains brightness information, and is used for brightness control. Further, the display signal is transmitted to a display control unit (DCU) 34. The display control unit 34 generates a brightness signal S_{B} in order to control a variable current source 60 of the cathode electrode driving unit 40 which will be described later. The brightness signal S_{B} is produced based on the display signal and controls the emission brightness. The brightness signal S_{B} is a current control signal that controls a magnitude of a current flowing in a PMOS 64 of the variable current source 60.

The display address signal includes information on a two-dimensional position where the information determined by the brightness signal S_{B} is to be located in the display panel 20. The display address signal is transmitted to a cathode address control unit (CACU) 32 and a gate address control unit (GACU) 33. The cathode address control unit 32 generates cathode select signals S_{C1} to S_{Cn} that selects a cathode electrode row to be used for light emission. The gate address control unit 33 generates gate select signals S_{G1} to S_{Gm} for selecting a cathode electrode line to be used for light emission.

The gate electrode driving unit 50 includes P-MOSFETs (P-channel Metal Oxide Semiconductor Field Effect Transistors, hereinafter, referred to as “PMOSs”) and N-MOSFETs (N-channel Metal Oxide Semiconductor Field Effect Transistors, hereinafter, referred to as “NMOSs”). PMOSs 51₁ to 51ₘ and NMOSs 52₁ to 52ₘ are provided in the gate electrode driving unit 50. A drain of a PMOS (e.g., PMOS 51₁) is connected to that of an NMOS (e.g., NMOS 52₁), and a gate electrode (e.g., gate electrode 102₁) is connected to a connection node of the drains thereof. Accordingly, the gate electrodes 102₁ to 102ₘ are driven with the combination of the PMOSs 51₁ to 51ₘ and the NMOSs 52₁ to 52ₘ. Further, a positive voltage V_{CCG} is supplied to a source of each of the PMOSs 51₁ to 51ₘ, and a source of each of the NMOSs 52₁ to 52ₘ is at ground potential. The P-MOSFET and the N-MOSFET are referred to as FET.

The gate of the PMOS (e.g., PMOS 51₁) is connected to that of the NMOS (e.g., NMOS 52₁), and a gate select signal (e.g., gate select signal S_{G1}) is applied to the connection de therebetween. Accordingly, the gate electrodes 102₁ to 102ₘ are driven by the gate select signals S_{G1} to S_{Gm}, respectively. Here, each of the gate select signals S_{G1} to S_{Gm} is a binary signal having a high level value and a low level value. When a gate select signal is at a high level, the PMOS is turned OFF and the NMOS is turned ON. On the other hand, when the gate select signal is at a low level, the corresponding PMOS becomes ON and the corresponding NMOS becomes OFF. That is, the PMOSs 51₁ to 51ₘ and the NMOSs 52₁ to 52ₘ of the gate electrode driving unit 50 serve as switch devices that switch between ON and OFF complementarily.

The cathode electrode driving unit 40 has PMOSs 41₁ to 41ₙ, NMOSs 42₁ to 42ₙ and NMOSs 43₁ to 43ₙ. A drain of a PMOS (e.g., PMOS 41₁) is connected to that of an NMOS (e.g., NMOS 42₁), and a cathode electrode (e.g., cathode electrode 101₁) is connected to a connection node therebetween. The cathode electrodes 101₁ to 101ₙ are driven with a combination of PMOSs 41₁ to 41ₙ, NMOSs 42₁ to 42ₙ and NMOSs 43₁ to 43ₙ. Further, a gate of the PMOS (e.g., PMOS 41₁) is connected to that of the NMOS (e.g., NMOS 43₁), and a cathode select signal (e.g., cathode select signal S_{C1}) is inputted to the connection node therebetween. As a consequence, the cathode electrodes 101ₗ to 101ₙ are controlled by the cathode select signals S_{C1} to S_{Cn}, respectively.

Moreover, a positive voltage V_{CCC} is supplied to each of the sources of the PMOSs 41₁ to 41ₙ. The drains of the NMOSs 43₁ to 43ₙ are connected to sources of the NMOSs 42₁ to 42ₙ, respectively.

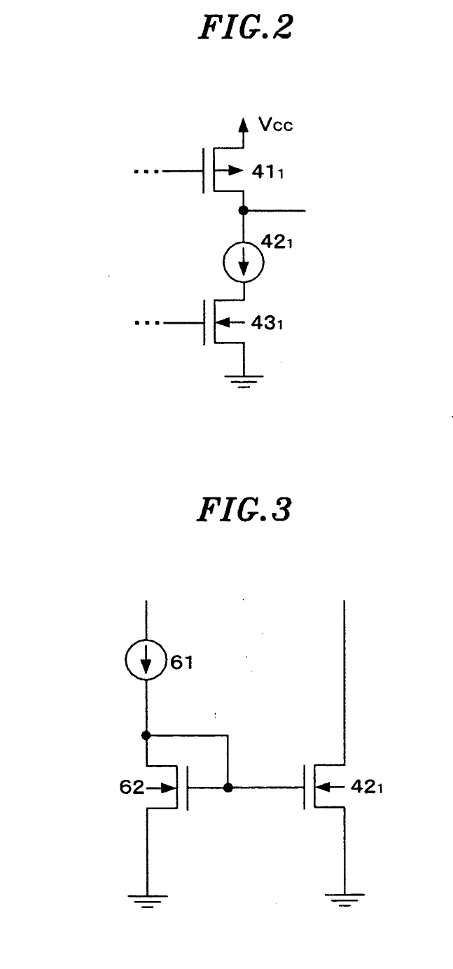

FIG. 2 explains connection relationship and functions of one PMOS and two NMOSs which form a part of a principal portion of the driving circuit by using the PMOS 41₁ and the NMOSs 42₁ and 43₁ as an example. The PMOS 41₁ and the NMOS 43₁ serve as analog switch devices. That is, the PMOS 41₁ is controlled to be ON (conductive state between the source and the drain of the PMOS 41₁) or OFF (non-conductive state between the source and the drain thereof) by changing a potential of the gate of the PMOS 41₁. Further, the NMOS 43₁ is controlled to be ON or OFF (conductive or non-conductive state between the source and the drain of the NMOS 43₁) by changing a potential of the gate of the NMOS 43₁.

Here, as shown in FIG. 1, the gate of the PMOS 41₁ and that of the NMOS 43₁ are connected with each other and the cathode select signal S_{c1} which has a high and a low value is inputted to the connection node between the PMOS 41₁ and NMOS 43₁. The voltage swing between the high and the low value of the cathode select signal S_{c1} is large enough to drive the PMOS 41₁ and the NMOS 43₁ to be completely ON and OFF, or vice versa. Therefore, when the PMOS 41₁ is ON, the NMOS 43₁ is OFF. Further, when the PMOS 41₁ is OFF, the NMOS 43₁ is ON. That is, the PMOS 41₁ and the NMOS 43₁ serve as an analog switch device that controls whether or not an analog current having a predetermined analog value flows from the cathode electrode 101₁.

Meanwhile, the NMOS 42₁ serves as a current source. When the NMOS 43₁ is ON and the PMOS 41₁ is OFF, a current of a predetermined magnitude flows from the NMOS 42₁ to the NMOS 43₁. At this time, no current flows in the PMOS 41₁ that is OFF, and the current from the cathode electrode 101₁ connected to the drain of the NMOS 42₁ flows into the drain of the NMOS 42₁. Further, when the NMOS 43₁ is OFF and the PMOS 41₁ is ON, no current flows from the NMOS 42₁ serving as the current source. This is because a path where a current of a predetermined magnitude flows from the NMOS 42₁ is blocked. In this case, the PMOS 41₁ is made to be ON in order to clamp a potential of the cathode electrode 101₁ to a voltage Vccc and prevent the potential of the cathode electrode 101₁ from being left undefined. Especially, in a display using an FED, a high voltage of 3 KV is applied to the anode electrode, so that it is preferable to prevent a high voltage from being applied to the cathode electrode 01₁. The above description is also applied to the operations of the sets of the PMOS 41₂ and the NMOSs 42₂ and 43₂, the PMOS 41₃ and the NMOSs 42₃ and 43₃, . . . , and the PMOS 41ₙ and the NMOSs 42ₙ and 43ₙ which operate in a same way.

FIG. 3 explains how the NMOS 42₁ forming another part of the principal portion of the driving circuit functions as a current source. In FIG. 3, the NMOS 63 connected to the NMOS 62 and the NMOS 43₁ connected to the NMOS 42₁ are omitted. FIG. 3 illustrates the so-called current mirror circuit. That is, the gate of the NMOS 62 is connected to that of the NMOS 42₁. When the NMOS 62 and the NMOS 42₁ have same characteristics, a magnitude of a current flowing between the drain and the source of the NMOS 42₁ is same as that of the current flowing between the drain and the source of the NMOS 62.

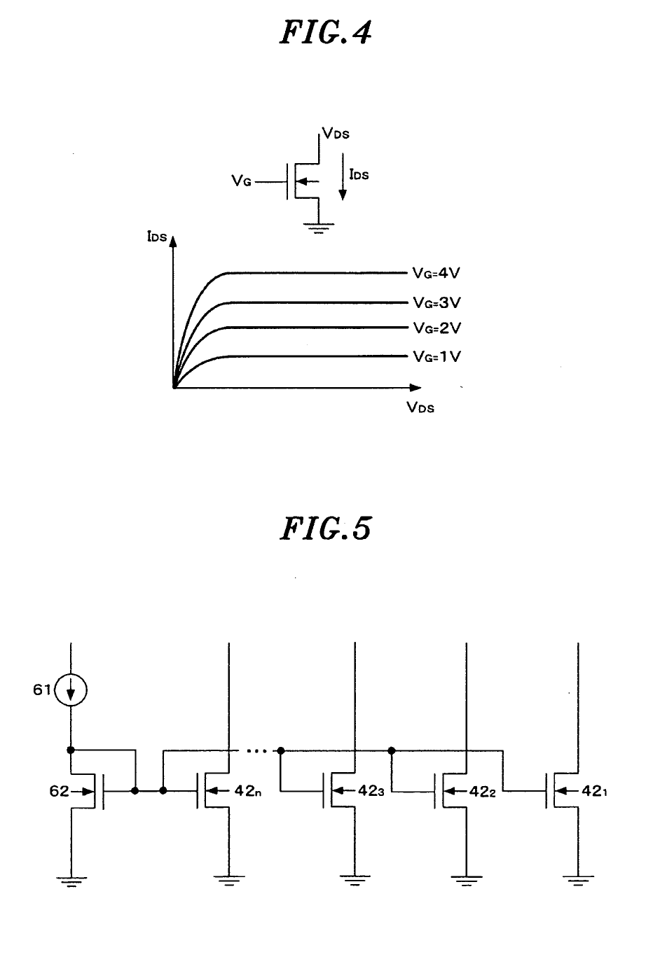

The reason thereof will be described hereinafter with reference to FIG. 4. FIG. 4 is a graph showing the characteristics of the NMOS. A vertical axis indicates a current Ids flowing between the drain and the source, and a horizontal axis indicates a voltage Vds between the drain and the source. The voltage V_{G} is a potential of the gate. In this case, since the source is grounded, the voltage V_{G} is a voltage between the gate and the source. In the so-called saturated region, the current Ids is determined by a magnitude of a voltage V_{G}, and is not dependent on the voltage Vds. The drain and the gate of the NMOS 62 are connected, so that the NMOS 62 operates in the saturated region. Further, the NMOS 61 serving as a current source is connected to the drain of the NMOS 62, so that a gate potential required to flow a current from the NMOS 61 between the drain and the source of the NMOS 62 is generated in the gate of the NMOS 62. Therefore, the current of a same magnitude as that from the current source (NMOS 61) flows in the NMOS 42₁ having a gate potential of a same magnitude as that of the NMOS 62.

FIG. 5 is an enlarged view of the NMOSs 42₁ to 42ₙ in FIG. 1 which forms another part of the principal portion of the driving circuit. In FIG. 5, the NMOSs 43₁ to 43ₙ connected to sources of the NMOSs 42₁ to 42ₙ are omitted. As can be seen from FIG. 5, the gates of the NMOS 42₁ to 42ₙ are connected in parallel to the gate of the NMOS 62, so that a current of a same magnitude can be made to flow between the drains and the sources of the NMOSs 42₁ to 42ₙ. Further, a current of a same magnitude can be made to flow into the cathode electrodes 101₁ to 101ₙ connected to the drains of the NMOSs 42₁ to 42ₙ.

Hereinafter, the relationship between the NMOS 63 and the NMOSs 43₁ to 43ₙ will be described. As set forth above, the NMOSs 43₁ to 43ₙ serve as analog switch devices. In an actual operation of each analog switch device, however, drain-source voltages are generated between drains and sources of the NMOSs 431 to 43n. Therefore, the gate-source voltages of the NMOSs 42₁ to 42ₙ are reduced by the drain-source voltages, respectively, so that the gate-source voltage of the NMOS 62 becomes different from those of the NMOS 42₁ to 42ₙ if the source of the NMOS 62 is grounded. Accordingly, the current mirror circuit does not operate properly. In the circuit shown in FIG. 1, therefore, the NMOS 63 is provided to improve the accuracy of the current mirror. The voltage V_{CB} applied to the gate of the NMOS 63 is set to the high-level voltage of the cathode select signals S_{C1} to S_{Cn} respectively applied to the NMOS 43₁ to 43ₙ. Therefore, the drain-source voltage of the NMOS 63 becomes the same as that of the drain-source voltage when the NMOS 43₁ to 43ₙ are ON. As a result, the current mirror circuit can operate with high accuracy even when the NMOSs 43₁ to 43ₙ are provided.

The NMOSs 43₁ to 43ₙ serve as analog switch devices for disconnecting current paths through which the cathode electrodes are connected in series with the NMOSs 42₁ to 42ₙ serving as current sources. Thus, connection between the NMOSs may be altered as follows: The drains of the NMOSs 431₁ to 431ₙ are connected to the drains of the PMOSs 41₁ to 41ₙ, and the sources thereof are connected to the drains of the NMOSs 42₁ to 42ₙ whose sources are grounded. Further, the cathode electrodes are connected to the connection nodes between the drains of the PMOSs 41₁ to 41ₙ and those of the NMOSs 43₁ to 43ₙ. When such a connection type is employed, the NMOSs 43₁ to 43ₙ do not affect the gate-source voltage of the NMOSs 42₁ to 42ₙ and, hence, there is no need to employ the NMOS 63 and therefore, the NMOS 63 can be omitted.

The cathode electrode driving unit 40 includes the variable current source 60. The variable current source 60 has the aforementioned PMOSs 61 and 64, NMOSs 62 and 63, the differential amplifier 65 and the resistor 66. The variable current source 60 has a function of setting a current level of the PMOS 61 serving as a current source that generates a current of a reference magnitude. The gate of the PMOS 64 is connected to that of the PMOS 61, forming another current mirror circuit. Accordingly, the magnitude of the current flowing between the source and the drain of the PMOS 64 becomes the same as that of the current flowing between the source and the drain of the PMOS 61.

The magnitude of the current flowing between the source and the drain of the PMOS 64 is detected in terms of a voltage by the resistor 66 connected to the drain of the PMOS 64, and then is inputted into a positive input end of the differential amplifier 65. Further, a brightness signal S_{B} is inputted into a negative input end of the differential amplifier 65, so that the voltage of the resistor 66 is feedback-controlled to be made same as that of the brightness signal S_{B} as a reference value. Here, both end voltages of the resistor 66 are obtained by multiplying the current flowing in the resistor 66 by the resistance of the resistor 66, so that the magnitude of the current flowing in the resistor 66, i.e., the magnitude of the current flowing between the source and the drain of the PMOS 64, can be controlled by the brightness signal S_{B}.

By combining the two current mirrors, the magnitude of the current flowing in the cathode electrodes 101₁ to 101ₙ can be controlled with high accuracy by the brightness signal S_{B}. Moreover, a magnitude of current flowing in a single cathode electrode is considerably small, e.g., about 1 μA.

Hereinafter, the operation of the display 10 will be described.

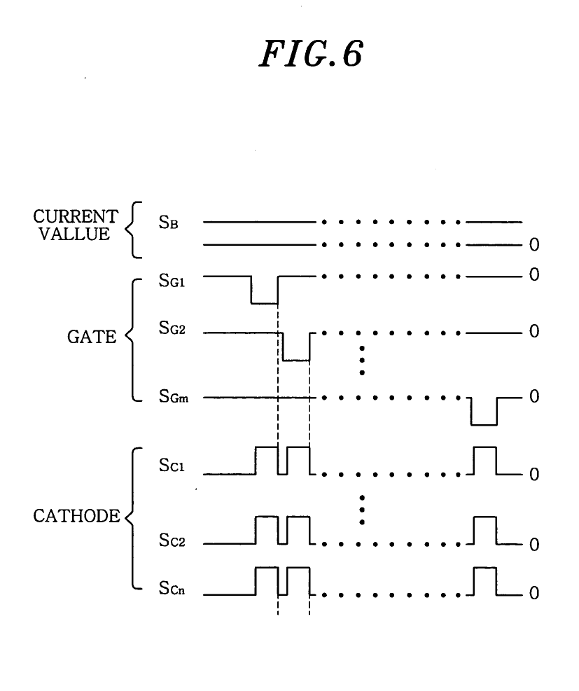

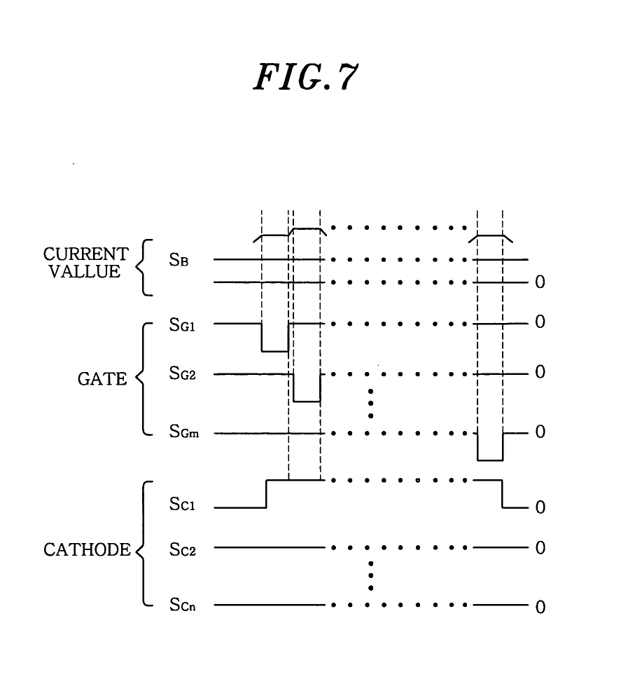

FIGS. 6 and 7 explain an operation of the display 10 with reference to the signals of each unit. FIG. 6 illustrates a case where all the dots are on, i.e., each of the dots emits a same amount of electrons and each phosphor corresponding to each dot emit light of a same brightness. From the top of FIG. 6, there are illustrated a current value flowing in the cathode electrode controlled by the brightness signal S_{B}, gate select signals for controlling the gate electrodes and cathode select signals for controlling the cathode electrodes. In FIG. 6, the gate select signals S_{G1}, S_{G2} and S_{Gm} and the cathode select signals S_{C1}, S_{C2} and S_{Cn} are illustrated, whereas the remaining gate select signals and the remaining cathode select signals are omitted. Moreover, a horizontal axis of each signal indicates time.

Referring to FIG. 6, the brightness signal S_{B} maintains a constant voltage (ensuring perceivable brightness), so that the magnitude of the current flowing between the source and the drain of the PMOS 64 is controlled to be set at a predetermined level constantly. In that state, while the gate select signal S_{g1} is low, all of the cathode select signals S_{c1} to S_{cn} are high, so that NMOSs 43₁ to 43ₙ become ON. Therefore, a same amount of current flows in each of cathode electrodes 101₁ to 101ₙ, whereby whole surface of the display panel 20 emits lights of a same brightness.

FIG. 7 depicts a control method of sequentially changing the brightness signal S_{B} and setting brightness in two-dimensional coordinates on a display panel in accordance with the brightness signal S_{B}.

In FIG. 7, the level of the brightness signal S_{B} changes whenever each dot is selected, and the magnitude of the current flowing between the source and the drain of the PMOS 64 is controlled to vary in accordance with the brightness signal S_{B}. In that state, the cathode signal S_{c1} only is high while the gate signal S_{g1} is low, the current can flow only in the cathode electrode 101₁ and, also, the current in accordance with the brightness signal S_{B} flows in the dot of the intersection of the gate electrode 102₁ and the cathode electrode 101₁.

Next, if only the cathode select signal S_{c1} is high while the gate select signal S_{g2} is low, the current in accordance with the brightness signal S_{B} flows in the dot of the intersection of the gate electrode 102₂ and the cathode electrode 101₁. With such sequential scanning, it is possible to sequentially and separately control the current values of the respective dots disposed over the entire two-dimensional surface of the display panel 20, and also possible to control the brightness of the phosphor of the corresponding dot to a desired level. That is, a desired two-dimensional image can be displayed.

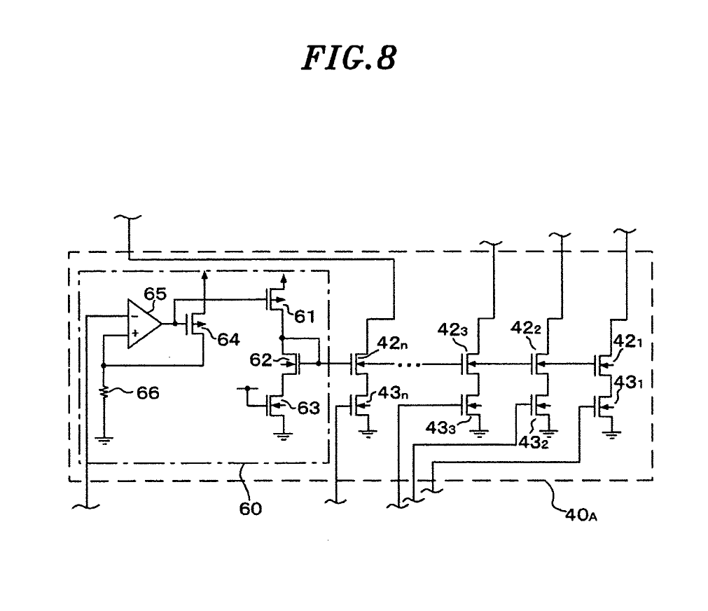

FIG. 8 describes a modification of the driving circuit. In FIG. 8, a circuit 40A is the modification of the cathode electrode driving circuit 40 in FIG. 1. The other parts that are not shown in FIG. 8 are the same as those shown in FIG. 1. In the circuit in FIG. 8, the PMOS 41₁ to 41ₙ are not provided. This modified circuit still has a same current driving effect as the original circuit in FIG. 1. As described above, however, when NMOSs 43₁ to 43ₙ are OFF, each of the cathode electrodes 101₁ to 101ₙ may have an undefined voltage value. Such case is not preferred in FED using high voltage of about 3 KV in the display apparatus. However, the above circuit can be suitably employed in an EL in which no high voltage is applied to anode electrodes.

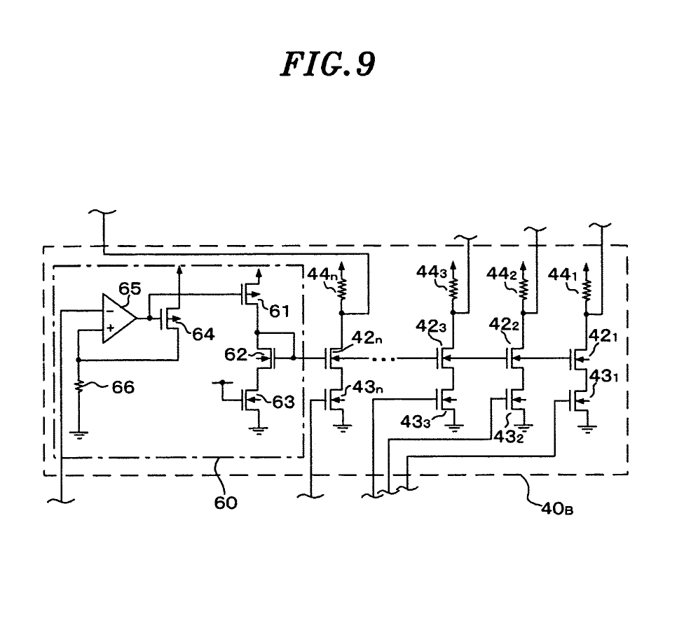

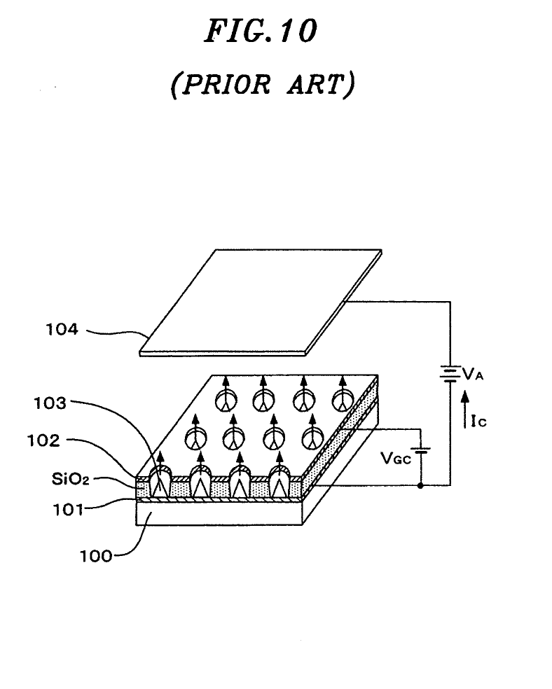

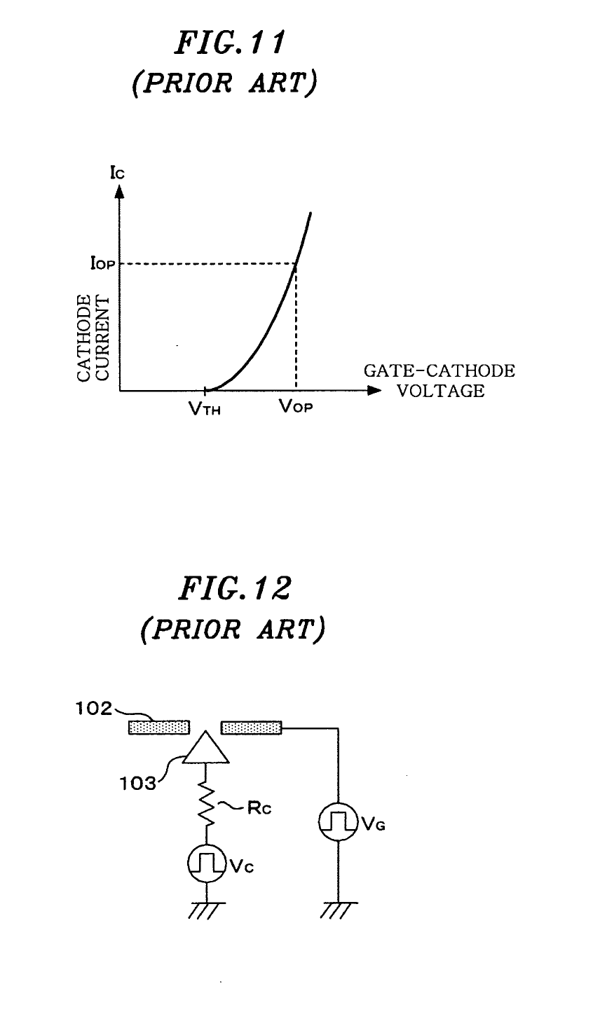

FIG. 9 shows another modification of the driving circuit. In FIG. 9, a circuit 40B is the modification of the cathode electrode driving circuit 40 in FIG. 1. The other parts that are not shown in FIG. 9 are the same as those shown in FIG. 1. In the circuit in FIG. 9, resistors 44₁ to 44ₙ are installed instead of the PMOSs 41₁ to 41ₙ. In that case, it is possible to prevent the voltage of the cathode electrodes from being left undefined. However, currents flowing in the resistors 44₁ to 44ₙ flow in the NMOSs 42₁ to 42ₙ serving as current sources, respectively, and, thus, the current errors need to be reduced by increasing the resistances of the resistors 44₁ to 44ₙ.

The principal portion of the driving circuit of the display panel in accordance with the above embodiment will be described hereinafter. In the following description, an arbitrary cathode electrode is indicated as the cathode electrode 101₁; an NMOS connected to the cathode electrode 101 is indicated as the NMOS 42; and the NMOS connected to the NMOS 42 is indicated as the NMOS 43.

This driving circuit is characterized by the cathode electrode driving unit 40 (first electrode driving unit) connected to the cathode electrode 101 (first electrode) of the display panel 20. The cathode electrode driving unit 40 has the first current mirror circuit fabricated by connecting the gate of the PMOS 64 (first FET) and the gate of the PMOS 61 (second FET) and the second current mirror circuit fabricated by connecting the gate of the NMOS 62 (third FET) and the gate of the NMOS 42 (fourth FET).

The gate of the PMOS 64 (first FET) is connected to an output end of the differential amplifier 65. Further, the connection node between the drain of the PMOS 64 and the resistor 66 (current detecting resistor) is connected to a positive input end of the differential amplifier 65, and the brightness signal S_{B} is inputted into a negative input end of the differential amplifier 65. With this connection, the current flowing in the PMOS 64 is detected in terms of a voltage by the register 66, and a feedback loop for controlling the detected voltage from the resister 66 to be made same as the brightness signal S_{B} is formed. As a result, the magnitude of the current flowing in the PMOS 64 is in accordance with the brightness signal S_{B}. As a consequence, the PMOS 64 serves as a reference current source.

The PMOS 61 of the first current mirror is connected in series with the NMOS 62 of the second current mirror. By employing such a connection, the current of a same magnitude as that of the current flowing in the PMOS 61 (second FET) is made to flow in the NMOS 62 (third FET).

Moreover, the NMOS 42 (fourth FET), the NMOS 43 (analog switch device) and the cathode electrode 101 are connected in series. Further, there is provided the cathode address control unit 32 that controls the NMOS 43 to be ON (conductive state) or OFF (non-conductive state). By employing such a connection, the current having a magnitude in accordance with a magnitude of the current from the reference current source can be made to flow to the cathode electrode 101₁ when the NMOS 43 is ON. Meanwhile, the current can be made not to flow in (the cathode electrode 101 when the NMOS 43 is OFF.

By employing the above driving circuit to the display, the current flowing in the cathode electrode 101 can be driven with high accuracy and, also, an image having no brightness variation can be obtained in spite of the temporal variation in characteristics and the spatial variation in characteristics.

Moreover, when the driving circuit is employed to the display, the temporal variation in characteristics does not cause the brightness variation. As a result, the durable time of the display can be prolonged.

The principal portion of the display in accordance with the above embodiment will be described hereinafter. This display has the display panel 20 that displays an image on a two-dimensional surface and a driving circuit that drives the display panel.

The display panel 20 has the plurality of cathode electrodes (first electrode) arranged in substantially parallel relationship and the plurality of gate electrodes (second electrode) arranged in substantially parallel relationship, the gate electrodes and the cathode electrodes being disposed substantially perpendicular to each other. By employing such a structure, in the display using an FED, the electrons are emitted from the intersections of the gate electrodes and the cathode electrodes. Further, the electron emission can be controlled by the driving circuit that controls the gate electrodes and the cathode electrodes.

In the display using an EL, respective EL devices are arranged in a two-dimensional matrix pattern. Moreover, anode electrodes of the ELs in one row or column of the two-dimensional matrix are connected to each other, thus forming anode electrodes in one direction of the two-dimensional matrix (second electrode). Cathode electrodes of the ELs in column or row of the two-dimensional matrix are connected to each other, thus forming cathode electrodes in the other direction of the two-dimensional matrix (first electrodes). Accordingly, the EL devices disposed at the intersections of the anode electrodes and the cathode electrodes emit lights, and the emission can be controlled by the driving circuit for controlling the anode electrodes and the cathode electrodes.

The driving circuit is characterized by the cathode electrode driving unit 40 (first electrode driving unit) connected to the cathode electrodes 101₁ to 101ₙ (a plurality of first electrodes) of the display panel 20. The cathode electrode driving unit 40 has the first current mirror circuit fabricated by connecting the gate of the PMOS 64 (first FET) and the gate of the PMOS 61 (second FET) and the second current mirror circuit fabricated by connecting the gate of the NMOS 62 (third FET) and those of the NMOSs 42₁ to 42ₙ (a plurality of FETs).

The gate of the PMOS (first FET) is connected to an output end of the differential amplifier 65. Further, the connection node between the drain of the PMOS 64 and the resistor 66 (current detecting resistor) is connected to a positive input end of the differential amplifier 65, and the current control signal is inputted into a negative input end of the differential amplifier 65. With this connection, the current flowing in the PMOS 64 is detected in terms of a voltage by the resister 66, and a feedback loop for controlling the detected voltage by the resister 66 to be same as that of the current control signal is formed. As a result, the magnitude of the current flowing in the PMOS 64 is in accordance with the current control signal, i.e. the brightness signal S_{B}. As a consequence, the PMOS 64 serves as a reference current source.

The PMOS 61 of the first current mirror is connected in series with the NMOS 62 of the second current mirror. By employing such a connection, the current having a magnitude same as that of the current flowing in the PMOS 61 (second FET) can flow in the NMOS 62 (third FET).

Moreover, the NMOSs 42₁ to 42ₙ (FETs) are connected in series with the NMOSs 43₁ to 43ₙ (analog switch devices) and the cathode electrodes 101₁ and 101ₙ (a plurality of first electrodes) , respectively. Further, there is provided the cathode address control unit 32 that controls the NMOSs 43₁ to 43ₙ to be ON (conductive state) or OFF (non-conductive state). By employing such a connection, by having at least one of the NMOSs 43₁ to 43ₙ (analog switch devices) to be ON, a current having a magnitude in accordance with a magnitude of the reference current source can be made to flow in the cathode electrode connected in series to the analog switch device. Further, by having at least one of the NMOSs 43₁ to 43ₙ (analog switch devices) to be OFF, the current can be made not to flow in the cathode electrode connected in series to the analog switch devices.

By employing the above driving circuit to the display, the current flowing in the cathode electrode 101 can be driven with high accuracy and, also, an image having no brightness variation can be obtained in spite of the temporal variation in characteristics and the spatial variation in characteristics.

Moreover, when the driving circuit is employed in the display, the temporal variation in characteristics does not cause the brightness variation. As a result, the durable time of the display can be prolonged.

In accordance with the present invention, there is employed a display panel in which cathode electrodes and gate electrodes (anode electrode in case of EL) are disposed to intersect with each other. Further, by connecting the driving circuits to the respective end portions of the cathode electrodes and the gate electrodes (anode electrodes in case of EL) instead of providing circuits at the intersections thereof, the current flowing in each of the dots can be controlled in accordance with the brightness signal contained in the cathode electrode control signal. Accordingly, the variety of the combination type of the display panel and the driving circuit can be increased, and the application capability becomes improved compare to the case of applying the active matrix type.

While the invention has been shown and described with respect to the embodiments, it will be understood by those skilled in the art that various changes and modification may be made without departing from the scope of the invention as defined in the following claims.

What is claimed is:

1. A driving circuit of a display panel for driving a first electrode of the display panel in which the first electrode and a second electrode arranged to cross each other, comprising:
a first current mirror circuit formed by connecting a gate of a first FET and a gate of a second FET;
a current detecting resistor connected to a drain of the first FET, for detecting a magnitude of the current flowing in the first FET;
a differential amplifier having an output end connected to a gate of the first FET, a positive input end connected to a connection node between the first FET and the current detecting resistor, and a negative input end to which a current control signal for controlling a magnitude of the current flowing in the first FET is inputted;
a second current mirror circuit formed by connecting a gate of a third FET connected in series to the second FET to a gate of a fourth FET;
an analog switch device connected in series to the fourth FET and the first electrode; and
a cathode address control unit for controlling the analog switch device to be a conductive state or a non-conductive state.

2. The driving circuit of a display panel of claim 1, wherein a drain of the fourth FET is connected to the first electrode; a source of the fourth FET is connected to the analog switch device; and a source of the third FET is connected to a fifth FET for controlling a voltage drop of the third FET to be same as that of the analog switch device in the conductive state.

3. The driving circuit of the display panel of claim 1, further comprising a sixth FET connected to the first electrode, for applying a specific voltage to the first electrode when the analog switch device is in the non-conductive state.

4. The driving circuit of the display panel of claim 1, wherein a plurality of the fourth FETs and a plurality of the analog switch devices are formed to correspond, and the cathode address control unit controls each of the plurality of analog switch devices between a conductive state and a non-conductive state.

5. A display comprising:
a display panel in which a plurality of first electrodes and a plurality of second electrodes are arranged to cross each other;
a first driving circuit for driving the first electrodes of the display panel; and
a second driving circuit for driving the second electrodes of the display panel,
wherein the first driving circuit includes:
a first current mirror circuit formed by connecting a gate of a first FET to a gate of a second FET;
a current detecting resistor connected to a drain of the first FET, for detecting a magnitude of a current flowing in the first FET;
a differential amplifier having an output end connected to a gate of the first FET, a positive input end connected to a connection node between the first FET and the current detecting resistor, and a negative input end to which a current control signal for controlling a magnitude of the current flowing in the first FET is inputted;
a second current mirror circuit formed by connecting a gate of a third FET connected to the second FET in series and gates of a plurality of fourth FETs;
a plurality of analog switch devices connected in series with the first electrodes and the fourth FETs; and
a cathode address control unit for controlling each of the analog switch devices to be a conductive state or a non-conductive state.

6. The display of claim 5, wherein the current control signal is a brightness signal for controlling emission brightness of the display panel.
